(19) United States
(12) Patent Application Publication
(10) Pub. No.: US 2024/0410959 A1
(43) Pub. Date: Dec. 12, 2024

(54) Apparatus And Method For Detecting Latent Defective Cell In Battery Pack

(71) Applicant: LG Energy Solution, Ltd., Seoul (KR)

(72) Inventors: Kyu-chul Lee, Daejeon (KR); Tae-Hyeok Jang, Daejeon (KR); Cheol-Taek Kim, Daejeon (KR); Jee-Soon Choi, Daejeon (KR)

(73) Assignee: LG Energy Solution, Ltd., Seoul (KR)

(21) Appl. No.: 18/701,016

(22) PCT Filed: Oct. 21, 2022
(86) PCT No.: PCT/KR2022/016209

§ 371 Date: Apr. 12, 2024

(30) Foreign Application Priority Data
Oct. 22, 2021 (KR) 10-2021-0142202

(51) Int. Cl. G01R 31/396; G01R 31/36; G01R 31/367; G01R 31/3842

(52) U.S. Cl. CPC G01R 31/396; G01R 31/3646; G01R 31/367; G01R 31/3842

(57) ABSTRACT

Disclosed is an apparatus and method for detecting a latent defective cell in a battery pack. In the apparatus according to the present disclosure, during charging of the battery pack according to a charging profile having a plurality of charging ranges, for each of first to N-th cells in each charging range, a controller is configured to acquires first cell voltage time-series data (measured data) in a former part of each of the plurality of charging ranges. Additionally, the controller is configured to determines predicted cell voltage time-series data in a latter part of each of the plurality of charging ranges by applying a deep learning model to the first cell voltage time-series data.

### CROSS-REFERENCE TO RELATED APPLICATION

The present application is a national phase entry under 35 U.S.C. § 371 of International Application No. PCT/KR2022/016209 filed Oct. 21, 2022, which claims priority from Korean Patent Application 10-2021-0142202 filed Oct. 22, 2021, all of which are incorporated herein by reference.

### TECHNICAL FIELD

The present disclosure relates to an apparatus and method for detecting a latent detecting a latent defective cell by statistically analyzing differences between measured values and predicted values of voltage behaviors of cells during the charging of a battery pack.

### BACKGROUND ART

As opposed to non-rechargeable primary batteries, rechargeable secondary batteries have a wide range of applications including small high-tech electronic devices such as smart phones, laptop computers or tablet computers as well as electric vehicles and energy storage systems (ESSs).

Since they can be used in a wide range of applications as described above, secondary batteries provide efficiency and convenience, but nevertheless, when overheated, they have explosion or fire risks due to high energy density.

In particular, recently, fire accidents caused by battery explosion aggravate concerns in the secondary battery market, and accordingly there is an urgent need to ensure safety of secondary batteries.

### SUMMARY

### Technical Problem

The present disclosure is designed under the above-described background, and therefore the present disclosure is directed to providing an apparatus and method for detecting a latent defective cell among cells in a battery pack during the charging of the battery pack to improve safety of the battery pack.

### Technical Solution

To solve the above-described technical problem, an apparatus for detecting a latent defective cell in a battery pack according to an aspect of the present disclosure includes a voltage sensor, a current sensor and a temperature sensor to measure a voltage, a current and a temperature of first to N-th cells included in the battery pack during charging of the battery pack, respectively, and a controller connected to the voltage sensor, the current sensor and the temperature sensor.

Preferably, during the charging of the battery pack according to a charging profile having a plurality of charging ranges, for each of the first to N-th cells in each charging range, in each charging grange of the plurality of charging rangesl the controller may be configured to acquire first cell voltage time-series data through the voltage measurement unit in a former part of the charging range. Additionally, the controller may be configured to determine predicted cell voltage time-series data in a latter part of the charging range by applying a deep learning model to the first cell voltage time-series data. Additionally, the controller may be configured to acquire second cell voltage time-series data through the voltage sensor in the latter part of the charging range, and determine an error between the second cell voltage time-series data and the predicted cell voltage time-series data. Additionally, the controller may be configured to determine that any cell in which the determined error is larger than corresponding errors of other cells in at least one of the plurality of charging ranges is one of the latent defective cells.

According to an aspect, the error is a maximum difference between the second cell voltage time-series data and the predicted cell voltage time-series data and wherein the controller is configured to:

For each of the plurality of charging ranges, the controller may be configured to determine a first average of the errors of the first to N-th cells and a first standard deviation of the errors of the first to N-th cells; for each error of the first to N-th cells, compute a first standardized value of the error that is equal to a ratio of (i) a difference between the error and the first average to (ii) the first standard deviation”, and determine that any cell in which the first standardized value is larger than the first threshold in at least one of the plurality of charging ranges is one of the latent defective cells.

Preferably, the deep learning model may be pre-trained, using the first cell voltage time-series data and the second cell voltage time-series data of first to m-th training cells respectively measured in the former part and the latter part of each of the plurality of charging ranges, to receive an input of the first cell voltage time-series data and output a predicted cell voltage time-series data having a minimum error compared to the second cell voltage time-series data.

According to another aspect, the error is a maximum difference between the second cell voltage time-series data and the predicted cell voltage time-series data, and wherein the controller is configured to: for each of the plurality of charging ranges; for each error of the first to N-th cells, compute a first standardized value of the error that is equal to a ratio (i) a difference the error and−a first average to (ii) a first standard deviation and determine any cell in which the first standardized value is larger than a first threshold in at least one of the plurality of charging ranges is one of the latent defective cells. Here, the first average and the first standard deviation may be pre-determined by the deep learning model during the training process of the deep learning model.

Optionally, the controller may be configured to, for each of first to p-th modules of the battery pack, determine a second average and a second standard deviation of the error of those cells of the first to N-th cells that are included in the module; for each error of those cells of the first to N-th cells that are included in the module, compute a second standardized value of the error that equals a ratio of (i) a difference between the error−and the second average to (ii) the second standard deviation” and determine that any cell in which the first standardized value is larger than the first threshold and the second standardized value is larger than a second threshold in at least one of the plurality of charging ranges is one of the latent defective cells.

Optionally, the controller may be configured to, for each of the first to N-th cells, monitor if a relative change behavior of the second cell voltage time-series data and the predicted cell voltage time-series data in each of the plurality of the charging ranges shifts matches a predefined change behavior pattern for a latent defect type, and determine whether the latent defect type of any cell for which the predefined change behavior pattern is found occurs within a reference number of times or more.

Preferably, the predefined change behavior pattern may occur when the second cell voltage time-series data increases faster than the predicted cell voltage time-series data in any of the plurality of charging ranges at a first stage and the predicted cell voltage time-series data increases faster than the second cell voltage time-series data in the charging range at a second stage, and the latent defect type includes a lithium plating at a negative electrode.

The apparatus according to the present disclosure may further €de a recording storage medium configured to store data, a predefined parameter, a program or a combination thereof; and a display. Additionally, the controller may be configured to record identification information associated with the determined latent defective cell in the storage medium, or output a message notifying that the latent defective cell is detected in the battery pack through the display, or transmit the identification information of the latent defective cell to an external device.

The technical problem according to the present disclosure may be solved by a battery management system including the above-described apparatus for detecting a latent defective cell in a battery pack.

To solve the above-described technical problem, a method for detecting a latent defective cell in a battery pack according to another aspect of the present disclosure includes, during charging of the battery pack according to a charging profile having a plurality of charging ranges, for each of first to N-th cells in each charging range, in each charging range of the plurality of charging ranges: acquiring first cell voltage time-series data in a former part of the charging range; determining predicted cell voltage time-series data in a latter part of each of the plurality of charging ranges by applying a deep learning model to the first cell voltage time-series data; acquiring second cell voltage time-series data in the latter part of each of the plurality of charging ranges; determining an error between the second cell voltage time-series data and the predicted cell voltage time-series data; € determining that any cell in which the determined error is a larger than corresponding errors of other cells in at least one of the plurality of charging ranges is one of the latent defective cell.

### Advantageous Effects

According to the present disclosure, it is possible to easily detect a latent defective cell by dividing the charging profile of the battery pack into the plurality of charging ranges, and statistically comparing and analyzing the behaviors of the actually measured voltage and the predicted voltage for each charging range. Accordingly, it is possible to prevent human accidents by detecting latent defects directly related to fire or explosion accidents, especially, serious latent defects such as lithium plating at the negative electrode in the early stage and providing warnings to users. Additionally, in addition to the lithium plating at the negative electrode, the present disclosure may detect voltage change behaviors caused by swelling or micro short circuits, thereby effectively dealing with other latent defects.

### BRIEF DESCRIPTION OF THE DRAWINGS

The accompanying drawings illustrate an exemplary embodiment of the present disclosure, and together with the following detailed description, serve to provide a further understanding of the technical aspect of the present disclosure, and thus the present disclosure should not be construed as being limited to the drawings.

FIG. 1 is a schematic block diagram of an apparatus for detecting a latent defective cell in a battery pack according to an embodiment of the present disclosure.

FIG. 2 is a graph showing an example of a charging profile according to an embodiment of the present disclosure.

FIG. 3 is a graph showing voltage change behaviors of cells during the charging of a battery pack according to the charging profile shown in FIG. 2.

FIG. 4 is a graph showing an example of a former part and a latter part of a charging range set in a charging profile according to an embodiment of the present disclosure.

FIG. 5 is a graph showing an example of first and second cell voltage time-series data measured in each charging range during the charging of first to m-th training cells according to a charging profile of an embodiment of the present disclosure.

FIG. 6 is a graph showing changes in second cell voltage time-series data V_{k,i}(j) measured in the latter part of a charging range \textcircled{2} of a charging profile for a specific cell in which a latent defect is detected, predicted cell voltage time-series data V*_{k,i}(j) predicted by a deep learning model and “V_{k,i}(j)−V*_{k,i}(j)” corresponding to a difference between them.

FIG. 7 is a graph showing changes in second cell voltage time-series data V_{k,i}(j) measured in the latter part of charging ranges \textcircled{1} to \textcircled{5} of a charging profile for a specific cell having lithium plating at a negative electrode, predicted cell voltage time-series data V*_{k,i}(j) predicted by a deep learning model and “V_{k,i}(j)−V*_{k,i}(j)” corresponding to a difference between them.

FIGS. 8 to 10 are flowcharts showing the sequence of a method for detecting a latent defective cell in a battery pack according to an embodiment of the present disclosure.

### DETAILED DESCRIPTION

Hereinafter, an exemplary embodiment of the present disclosure will be described with reference to the accompanying drawings. Prior to the description, it should be understood that the terms or words used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation. Therefore, the embodiments described herein and the illustrations in the drawings are just an exemplary embodiment of the present disclosure, but not intended to fully describe the technical aspect of the present disclosure, so it should be understood that a variety of other equivalents and modifications could have been made thereto at the time of filing the patent application.

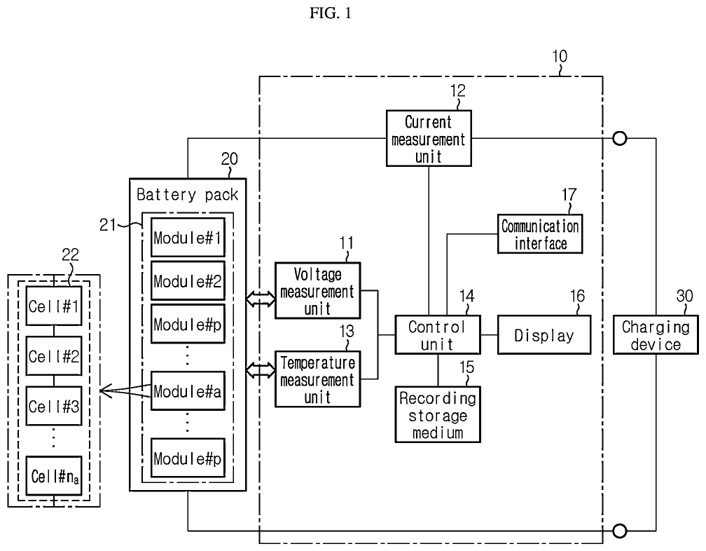

FIG. 1 is a schematic block diagram of an apparatus for detecting a latent defective cell in a battery pack according to an embodiment of the present disclosure.

Referring to FIG. 1, the apparatus 10 according to an embodiment of the present disclosure is designed to detect a latent defective cell in a battery pack 20 while the battery pack 20 is being charged by a charging device 30 according to a charging profile having a plurality of charging ranges.

The latent defective cell refers to a cell showing an abnormal voltage change behavior that is different from that of a normal cell. For example, in the case of a lithium polymer cell, when lithium plating at the negative electrode or a micro short circuit or swelling in the cell occurs, voltage change behaviors during cell charging are different from that of a normal cell.

The battery pack 20 includes first to p-th modules 21. The first to p-th modules 21 may be connected in series and/or in parallel. An a-th module includes first to nₐ-th cells 22. The nₐ is the total number of cells included in the a-th module. The first to nₐ-th cells 22 may be connected in series and/or in parallel. The number of cells in each module may be equal or different. The total number of cells included in the battery pack 20 is

$${\sum }_{a = 1}^{p} {n}_{a} .$$

Hereinafter, the total number of cells included in the battery pack 20 may be defined as N, and all the cells in the battery pack 20 may be referred to as first to N-th cells.

In an embodiment, the first to N-th cells may be pouch-type lithium polymer cells. However, it is obvious that the present disclosure is not limited to the type of cell or packaging material. Accordingly, the present disclosure may be applied to any other type of secondary battery cell such as a lithium-sulfur battery, a sodium battery or the like. Additionally, the present disclosure may be applied to a cell having a structure of a cylindrical cell and a prismatic cell or the like.

The charging device 30 is a device that applies the charging current to the battery pack 20 according to the charging profile having the plurality of charging ranges. When the battery pack 20 is mounted in an electric vehicle, the charging device 30 may be a charging station. In another example, when the battery pack 20 is mounted in an energy storage system, the charging device 30 may be a Power Converting System (PCS) installed between the energy storage system and an electrical grid. The PCS is a system that controls the charge/discharge of the energy storage system.

In the present disclosure, the charging profile is a protocol defining changes in the magnitude of the charge current supplied to the battery pack 20 over time.

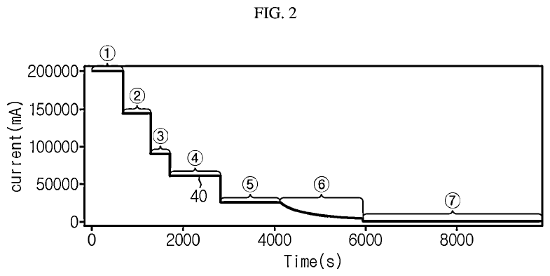

FIG. 2 is a graph showing an example of the charging profile 40 according to an embodiment of the present disclosure.

Referring to FIG. 2, the charging profile 40 has the plurality of charging ranges \textcircled{1} to \textcircled{7}. Each charging range differs in the magnitude and duration of the charging current. The duration is a period of time during which each charging range is maintained.

In an embodiment, the charging profile 40 is a step charging profile. In the step charging profile, the magnitude of the charging current decreases stepwise until the voltage of cells included in the battery pack 20 reaches the cut-off voltage, and subsequently, the magnitude of the charging current is adjusted according to a constant-voltage charging mode.

In FIG. 2, the charging ranges \textcircled{1} to \textcircled{5} are ranges in which the magnitude of the charging current decreases stepwise until the cut-off voltage, the charging range \textcircled{6} is a range in which the constant-voltage charging mode is applied, and the charging range \textcircled{7} is a range in which the charging current of small magnitude substantially close to 0 is applied until the battery cell is fully charged. In the charging profile 40, the substantial charging range is the charging ranges \textcircled{1} to \textcircled{6}.

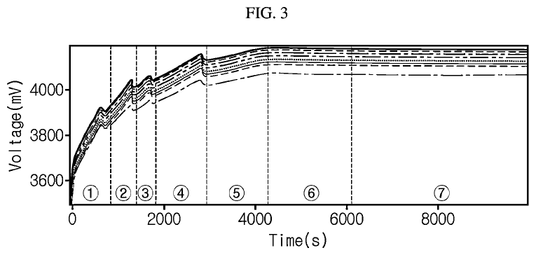

FIG. 3 is a graph showing the voltage change behaviors of cells during the charging of the battery pack 20 according to the charging profile 40 shown in FIG. 2.

The cells are lithium polymer cells that operate at 3.2V to 4.2V. The total number of cells is 100, and since the degree of degradation of the cells is not the same, the voltage change behaviors of the cells are different.

Meanwhile, the present disclosure is not limited to a specific change pattern of the charging profile 40. Accordingly, the charging profile 40 of FIG. 2 is just an example. It should be understood that when a certain charging profile has a plurality of charging ranges, the corresponding profile corresponds to the charging profile according to the present disclosure.

Referring back to FIG. 1, the apparatus 10 according to the present disclosure includes a voltage measurement unit 11, a current measurement unit 12, a temperature measurement unit 13 and a control unit 14.

The voltage measurement unit 11 measures the voltage of the first to N-th cells included in the battery pack 20 at a predetermined time interval during the charging of the battery pack 20 according to the charging profile 40 having the plurality of charging ranges, and outputs the cell voltage measurement value to the control unit 14.

The voltage measurement unit 11 may include a voltage measurement circuit known in the corresponding technical field, and since the voltage measurement circuit is well known, its description is omitted.

The current measurement unit 12 measures the magnitude of the charging current at a predetermined time interval during the charging of the battery pack 20 according to the charging profile 40 having the plurality of charging ranges, and outputs the current measurement value to the control unit 14.

The current measurement unit 12 may be a hall effect sensor or a sense resistor that outputs the voltage value corresponding to the magnitude of the electric current. The voltage value may be converted to the current value according to the ohm's law. When the cells in the first to p-th modules 21 are connected in series and the first to p-th modules 21 are also connected in series, the current measurement unit 12 may be installed on a line in which the charging current flows. In this example, the current measurement value measured by the current measurement unit 12 corresponds to the cell current value of all the cells included in the battery pack 20. It is obvious to those skilled in the art that when there are cells or modules connected in parallel, the current measurement unit 12 may be additionally installed at an optimal point of the line in which the charging current flows to measure the cell current value.

The temperature measurement unit 13 measures the temperature of the first to N-th cells at a predetermined time interval during the charging of the battery pack 20 according to the charging profile 40 having the plurality of charging ranges and outputs the cell temperature measurement value to the control unit 14.

The temperature measurement unit 13 may be a thermocouple or a temperature measurement device that outputs the voltage value corresponding to the temperature. The voltage value may be converted to the temperature value using a voltage-temperature conversion look-up table (function).

The temperature measurement unit 13 may be attached to each of the first to p-th modules 21. In this case, the temperature of each module may be regarded as the temperature of the cells included in the module. The present disclosure does not limit to install the temperature measurement unit 13 for each cell.

The control unit 14 acquires first and second cell voltage time-series data for each cell by periodically receiving the input of the cell voltage value of the first to N-th cells from the voltage measurement unit 11 in each charging range during the charging of the battery pack 20 according to the charging profile 40. Here, the cell voltage time-series data is a set of cell voltage data continuously measured at a plurality of time points.

In an embodiment, the first cell voltage time-series data is a set of cell voltage data measured in the former part of each charging range. Additionally, the second cell voltage time-series data is a set of cell voltage data measured in the latter part of each charging range.

The boundary of the former part and the latter part of the charging range may be arbitrarily set. In an example, when the duration of the i-th charging range is Tᵢ, the former part of the charging range is from the starting time of the charging range to time 0.3 Tᵢ, and the latter part of the charging range may from time 0.3 Tᵢ to time Tᵢ. In this example, the duration of the former part is 0.3 Tᵢ, and the duration of the latter part is 0.7 Tᵢ.

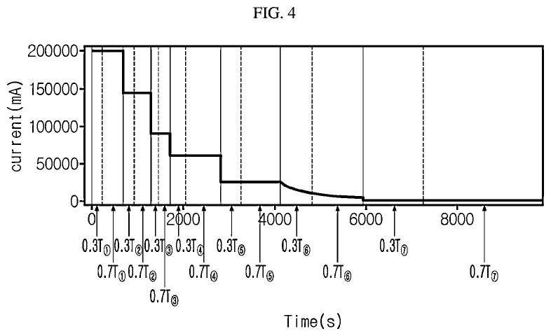

FIG. 4 is a graph showing an example of the former part and the latter part of the charging range set in the charging profile 40 according to an embodiment of the present disclosure.

In FIG. 4, the vertical solid line indicates the boundary between the charging ranges, and the dashed line indicates the boundary of the former part and the latter part of the charging range. The duration of the former part and the latter part of the charging range \textcircled{1} is 0.3 T_{\textcircled{1}} and 0.7 T_{\textcircled{1}}, respectively. Additionally, the duration of the former part and the latter part of the charging range \textcircled{2} is 0.3 T_{\textcircled{2}} and 0.7 T_{\textcircled{2}}, respectively. Additionally, the duration of the former part and the latter part of the charging range \textcircled{3} is 0.3 T_{\textcircled{3}} and 0.7 T_{\textcircled{3}}, respectively. Additionally, the duration of the former part and the latter part of the charging range \textcircled{4} is 0.3 T_{\textcircled{4}} and 0.7 T_{\textcircled{4}}, respectively. Additionally, the duration of the former part and the latter part of the charging range \textcircled{5} is 0.3 T_{\textcircled{5}} and 0.7 T_{\textcircled{5}}, respectively. Additionally, the duration of the former part and the latter part of the charging range \textcircled{6} is 0.3 T_{\textcircled{6}} and 0.7 T\textcircled{6}, respectively. Additionally, the duration of the former part and the latter part of the charging range \textcircled{7} is 0.3 T_{\textcircled{7}} and 0.7 T_{\textcircled{7}}, respectively.

The duration of the charging range may be different for each charging range. Additionally, the duration of the former part and the latter part of the charging range may be equal all over the entire charging range or different for each charging range. That is, the boundary of the former part and the latter part of the charging range may be set to an arbitrary time in the duration of the charging range.

Apart from acquiring the first and second cell voltage time-series data of the first to N-th cells through the voltage measurement unit 11 in each charging range, the control unit 14 may determine predicted cell voltage time-series data in the latter part of the charging range by applying a deep learning model to the first cell voltage time-series data in each charging range.

The deep learning model is a pre-trained model to receive the input of the first cell voltage time-series data measured in the former part of each charging range for each training cell during the charging of first to m-th training cells having the same specification as the cell in the battery pack 20 according to the above-described charging profile 40 and output the predicted cell voltage time-series data having a minimum error with the second cell voltage time-series data measured in the latter part of the corresponding charging range.

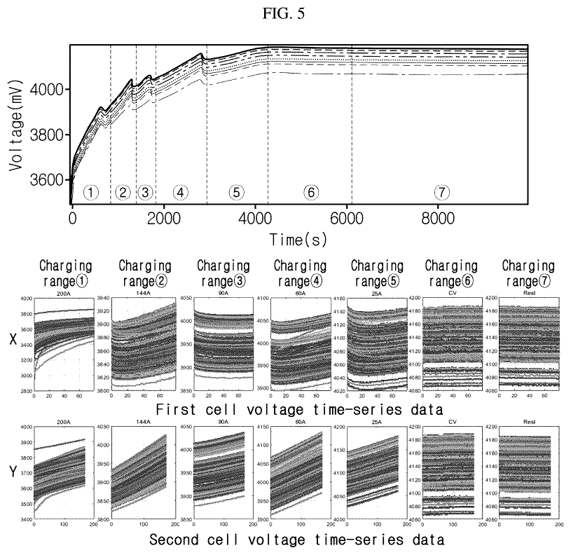

FIG. 5 is a graph showing an example of the first and second cell voltage time-series data measured in each charging range during the charging of the first to m-th training cells according to the charging profile according to an embodiment of the present disclosure.

The graph in the upper part of FIG. 5 shows exemplarily voltage curves of 100 training cells among m training cells in an overlapping manner, and the graph in the lower part of FIG. 5 shows exemplarily the first cell voltage time-series data and the second cell voltage time-series data measured in the charging ranges \textcircled{1} to \textcircled{7}.

Preferably, a few thousands to tens of thousands of training cells having different degrees of degradation may be used to improve the accuracy and reliability of the deep learning model during the training of the model.

Referring to FIG. 5, the deep learning model may be pre-trained to receive the input of the first cell voltage time-series data X measured in the training cells in the former part of the charging range \textcircled{1} and output the predicted cell voltage time-series data having the minimum error with the second cell voltage time-series data Y measured in the training cells in the latter part of the charging range \textcircled{1}. Additionally, the deep learning model may be pre-trained to receive the input of the first cell voltage time-series data X measured in the training cells in the former part of the charging range \textcircled{2} and output the predicted cell voltage time-series data having the minimum error with the second cell voltage time-series data Y measured in the training cells in the latter part of the charging range \textcircled{2}. Additionally, the deep learning model may be pre-trained to receive the input of the first cell voltage time-series data X measured in the training cells in the former part of the charging range \textcircled{3} and output the predicted cell voltage time-series data having the minimum error with the second cell voltage time-series data Y measured in the training cells in the latter part of the charging range \textcircled{3}. Additionally, the deep learning model may be pre-trained to receive the input of the first cell voltage time-series data X measured in the training cells in the former part of the charging range \textcircled{4} and output the predicted cell voltage time-series data having the minimum error with the second cell voltage time-series data Y measured in the training cells in the latter part of the charging range \textcircled{4}. Additionally, the deep learning model may be pre-trained to receive the input of the first cell voltage time-series data X measured in the training cells in the former part of the charging range \textcircled{5} and output the predicted cell voltage time-series data having the minimum error with the second cell voltage time-series data Y measured in the training cells in the latter part of the charging range \textcircled{5}. Additionally, the deep learning model may be pre-trained to receive the input of the first cell voltage time-series data X measured in the training cells in the former part of the charging range \textcircled{6} and output the predicted cell voltage time-series data having the minimum error with the second cell voltage time-series data Y measured in the training cells in the latter part of the charging range \textcircled{6}. Additionally, the deep learning model may be pre-trained to receive the input of the first cell voltage time-series data X measured in the training cells in the former part of the charging range \textcircled{7} and output the predicted cell voltage time-series data having the minimum error with the second cell voltage time-series data Y measured in the training cells in the latter part of the charging range \textcircled{7}.

More preferably, in addition to the first cell voltage time-series data measured in the former part of the charging range, the data used to train the deep learning model may further include time-series data of the cell current and the cell temperature measured in the former part of the charging range. In this case, the deep learning model may be trained to receive the input of the first cell voltage time-series data, the cell current time-series data and the cell temperature time-series data measured in the former part of the charging range and output the predicted cell voltage time-series data having the minimum error with the second cell voltage time-series data measured in the latter part of the charging range.

Preferably, the deep learning model may include any model based on an artificial neural network suitable to predict the time-series behavior of the cell voltage. For example, the artificial neural network may include Recurrent Neural Network (RNN), Convolution Neural Network (CNN) or the like. However, the present disclosure is not limited to the type of artificial neural network.

After the control unit 14 acquires the second cell voltage time-series data and the predicted cell voltage time-series data in the latter part of each charging range for each of the first to N-th cells in the battery pack 20, the control unit 14 may determine an error between the second cell voltage time-series data (the measured value) and the predicted cell voltage time-series data (the predicted value).

Additionally, the control unit 14 may monitor the error between the second cell voltage time-series data and the predicted cell voltage time-series data determined in each charging range for each of the first to N-th cells, and detect a cell having a larger error in at least one charging range as a latent defective cell.

Specifically, the control unit 14 may calculate the error E_{k,1}, between the second cell voltage time-series data V_{k,1}(j) and the predicted cell voltage time-series data V_{k,1}*(j) of the first cell for each charging range using the following Equation 1.

$${E}_{k , i} = max ( \vert {V}_{k , i} ( j ) - {{V}^{*}}_{k , i} ( j ) \vert ) , 1 \leq j \leq {Num}_{measure} \qquad < Equation 1 >$$

k: Index of charging range
E_{k,i}: Error of k-th charging range for i-th battery cell
V_{k,i}(j): j-th second cell voltage of i-th battery cell measured in the latter part of the k-th charging range
V*_{k,i}(j): j-th predicted cell voltage of i-th battery cell predicted by the deep learning model in the latter part of k-th charging range
Numₘₑₐₛᵤᵣₑ: Total number of times cell voltage is measured in the latter part of k-th charging range or the total number of times cell voltage is predicted using the deep learning model in the latter part of k-th charging range
max( ): Function that returns the maximum value among the plurality of input values

Additionally, the control unit 14 may calculate the error E_{k,2}, E_{k,3}, . . . , E_{k,n} between the second cell voltage time-series data and the predicted cell voltage time-series data of the second to N-th cells for each charging range.

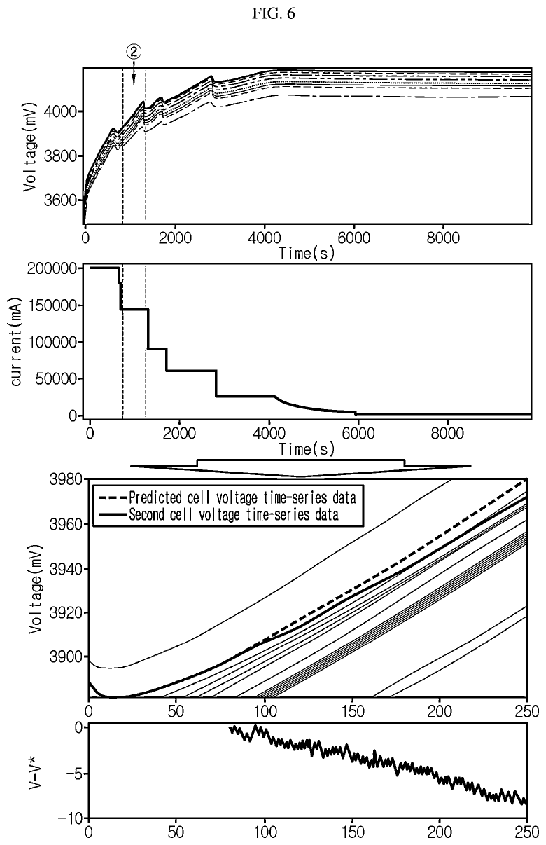

FIG. 6 is a graph showing changes in the second cell voltage time-series data V_{k,i}(j) measured in the latter part of the charging range \textcircled{2} of the charging profile 40 for a specific cell in which a latent defect is detected, the predicted cell voltage time-series data V*_{k,i}(j) predicted by the deep learning model and “V_{k,i}(j)−V*_{k,i}(j)” corresponding to a difference between them.

The black solid line indicates V_{k,i}(j), and the black dashed line indicates V*_{k,i}(j). Referring to FIG. 6, it can be seen that the latent defective cell has an increase in “V_{k,i}(j)−V*_{k,i}(j)” to a significant level in the specific charging range. Accordingly, the error E_{k,i} may be used as the parameter for the detection of the latent defective cell. For reference, the second cell voltage time-series data and the predicted cell voltage time-series data of cells having no latent defect are indicated by the grey lines and they match and cannot be distinguished.

Additionally, the control unit 14 may determine a first average Avrₖ and a first standard deviation σₖ of the error E_{k,i} of the first to N-th cells for each charging range using the following Equation 2.

$${Avr}_{k} = mean ( {E}_{k , i} ) , 1 \leq i \leq N \qquad < Equation 2 >$$

$${σ}_{k} = std ( {E}_{k , i} ) , 1 \leq i \leq N$$

i: Index of cell
N: Number of cells in battery pack
k: Index of charging range
E_{k,i}: Error of k-th charging range for i-th battery cell
mean( ): Function that returns the average value of the plurality of input values
std( ): Function that returns the standard deviation of the plurality of input values

Additionally, the control unit 14 may determine a first standardized value Std_Value_{k,i} of the error E_{k,i} of each of the first to N-th cells using the following Equation 3 for each charging range. When the number of charging ranges is Num_{charge}, the number of first standardized values Std_Value_{k,i} for each cell is Num_{charge}.

$${Std\_Value}_{k , i} = ( {E}_{k , i} - {Avr}_{k} ) / {σ}_{k} , 1 \leq k \leq {Num}_{charge} \qquad < Equation 3 >$$

i: Index of cell
k: Index of charging range
Num_{charge}: Number of charging ranges
Avrₖ: First average of k-th charging range
σₖ: First standard deviation of k-th charging range

Additionally, the control unit 14 may detect, as the latent defective cell, any of the first to N-th cells of the battery pack 20 in which the first standardized value Std_Value_{k,i} is larger than a preset first threshold in at least one charging range.

The first standardized value Std_Value_{k,i} is a factor indicating how much the error E_{k,i} of the i-th cell determined in the k-th charging range is far from the average error value Avrₖ on the basis of the standard deviation σₖ of error.

For example, when Std_Value_{k,i} is 2, a difference between E_{k,i} and the average error is double the standard deviation of error. Accordingly, any cell in which the first standardized value Std_Value_{k,i} is larger than other cells in the k-th charging range may be regarded as a cell in which a defect is likely to occur due to the relatively large error between the measured cell voltage and the predicted cell voltage. It is because a difference between voltage change behavior (change behavior of the second cell voltage) of the latent defective cell and voltage change behavior (change behavior of the predicted cell voltage) of normal cells is large.

Preferably, the first threshold may be set to 3 or more, more preferably 4 or more, and much more preferably 4.5 or more.

Meanwhile, in Equation 3, the first average Avrₖ and the first standard deviation σₖ of each charging range may be pre-determined in the training process of the deep learning model. That is, after the training of the deep learning model is completed, the first cell voltage time-series data, the second cell voltage time-series data and the predicted cell voltage time-series data may be collected during the charging of the first to m-th training cells according to the charging profile 40 having the plurality of charging ranges, and the error E_{k,i} of each charging range may be determined for each training cell. Additionally, the average and the standard deviation of the error E_{k,i} calculated using Equation 2 for each charging range may be preset as the first average Avrₖ and the first standard deviation σₖ.

Optionally, the control unit 14 may determine a second average Avr_{k,a} and a second standard deviation σ_{k,a} of the error E_{k,i} for each module using the following Equation 4. Preferably, the second average Avr_{k,a} and the second standard deviation σ_{k,a} are determined for each charging range.

$${Avr}_{k , a} = mean ( {E}_{k , i @ a} ) , 1 \leq i \leq {n}_{a} , 1 \leq k \leq {Num}_{charge} \qquad < Equation 4 >$$

$${σ}_{k , a} = std ( {E}_{k , i} ) , 1 \leq i \leq {n}_{a} , 1 \leq k \leq {Num}_{charge}$$

a: Index of module
i: Index of cell
nₐ: Total number of cells included in a-th module
k: Index of charging range
Num_{charge}: Total number of charging ranges
E_{k,i@a}: Error in k-th charging range for i-th cell in a-th module
mean( ): Function that returns the average value of the plurality of input values
std( ): Function that returns the standard deviation of the plurality of input values

Additionally, the control unit 14 may determine a second standardized value Std_Value*_{k,i} in the module for the error E_{k,i} of each of the first to N-th cells using the following Equation 5 for each charging range. The number of second standardized values Std_Value*_{k,i} in the module for each cell is Num_{charge}.

$${{Std\_Value}^{*}}_{k , i} = ( {E}_{k , i} - {Avr}_{k , a} ) / {σ}_{k , a} , \\ 1 \leq i \leq N , 1 \leq a \leq p , 1 \leq k \leq {Num}_{charge} \qquad < Equation 5 >$$

i: Index of battery cell, N is Total number of cells
a: Index of module, p is Total number of modules
k: Index of charging range, Num_{charge} is the total number of charging ranges
Avr_{k,a}: Second average defined for the module in which the cell is included
σ_{k,a}: Second standard deviation defined for the module in which the cell is included

Additionally, the control unit 14 may be configured to detect, as the latent defective cell, any cell in which the first standardized value Std_Value_{k,i} is larger than the first threshold and the second standardized value Std_Value*_{k,i} in the module is larger than a second threshold in at least one charging range.

The second standardized value Std_Value*_{k,i} is a factor indicating how much the error E_{k,i} of the cell determined in the k-th charging range is far from the average value Avr_{k,a} of error in the module on the basis of the standard deviation σ_{k,a} of error in the module.

For example, when Std_Value*_{k,i} is 2, a difference between E_{k,i} and the average error in the module is double the standard deviation of error in the module. Accordingly, any cell in which the second standardized value Std_Value*_{k,i} is larger than other cells in one module may be regarded as a cell in which a defect is likely to occur since the error between the measured cell voltage and the predicted cell voltage is larger than other cell in the module.

Preferably, the second threshold may be smaller than the first threshold. In an example, the second threshold may be preferably set to 3.0 or less, and more preferably 2.5 or less.

Optionally, the control unit 14 may be further configured to perform the logic that detects the latent defect type of the battery cell.

Specifically, the control unit 14 may monitor if a relative change behavior of the second cell voltage time-series data of the first to N-th cells measured in the latter part of each charging range and the predicted cell voltage time-series data predicted in the latter part of each charging range as the charging range shifts shows a predefined change behavior pattern for each latent defect type. Additionally, when the predefined change behavior is detected in the same cell in a reference number of times or more during a plurality of charging cycles, the control unit 14 may identify the corresponding cell as the latent defective cell and determine the latent defect type.

In an example, when lithium plating at the negative electrode occurs in the lithium polymer cell, the second cell voltage time-series data increases faster than the predicted cell voltage time-series data in the charging range at the early stage of charging. It is because the potential of the negative electrode increases at the early stage of charging when lithium plating at the negative electrode occurs. Since the cell voltage corresponds to a difference between the positive electrode potential and the negative electrode potential, when the negative electrode potential increases, a slope of change in cell voltage increases. As a result, the second cell voltage increases faster than the predicted cell voltage at the early stage of charging. Since the predicted cell voltage is a predicted voltage by the deep learning model, and thus shows voltage change behaviors close to normal cells at the early stage of charging, the increase in the predicted cell voltage is not sharp.

Additionally, as opposed to the foregoing description, the predicted cell voltage time-series data increases faster than the second cell voltage time-series data in the charging range at the later stage of charging. The potential of the negative electrode decreases slowly during charging, and when lithium plating at the negative electrode occurs, the amount of lithium participating in the electrochemical reaction decreases, and the potential decline of the negative electrode is lessened. When the potential decline of the negative electrode is lessened, the increase in cell voltage is lessened as much. As a result, in the charging range at the later stage of charging, rather, the predicted cell voltage increases faster than the second cell voltage. Since the predicted cell voltage is a predicted voltage by the deep learning model and shows voltage change behaviors close to normal cells at the later stage of charging, the potential decline of the negative electrode is not lessened.

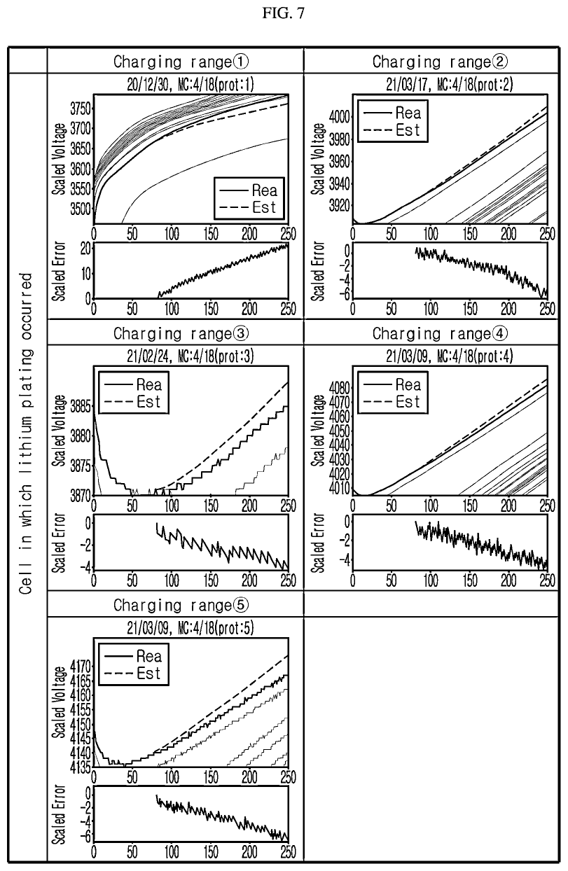

FIG. 7 is a graph showing changes in the second cell voltage time-series data V_{k,i}(j) measured in the latter part of the charging ranges \textcircled{1} to \textcircled{5} of the charging profile 40 for a specific cell in which lithium plating at the negative electrode occurred, the predicted cell voltage time-series data V*_{k,i}(j) predicted by the deep learning model and “V_{k,i}(j)−V*_{k,i}(j)” corresponding to a difference between them. In each graph, the horizontal axis is time (sec), and the vertical axis is voltage (milli-volt).

The black solid line indicates V_{k,i}(j), and the black dashed line indicates V*_{k,i}(j). As can be seen from FIG. 7, in the cell in which lithium plating occurred, the second cell voltage time-series data increases faster than the predicted cell voltage time-series data in the charging range \textcircled{1} at the early stage of charging. Additionally, in the charging ranges \textcircled{3}, \textcircled{4} and \textcircled{5}, on the contrary, the predicted cell voltage time-series data increases faster than the second cell voltage time-series data. The second cell voltage time-series data and the predicted cell voltage time-series data of cells having no latent defect are indicated by the grey lines and they match and cannot be distinguished.

In an embodiment, when the control unit 14 detects any of the first to N-th cells to show behaviors that the second cell voltage time-series data increases faster than the predicted cell voltage time-series data in the charging range at the early stage of charging and the predicted cell voltage time-series data increases faster than the second cell voltage time-series data in the charging range at the later stage of charging, the control unit 14 may identify the latent defect of the corresponding cell as lithium plating at the negative electrode.

Optionally, each time the control unit 14 detects any of the first to N-th cells to show behaviors that the second cell voltage time-series data increases faster than the predicted cell voltage time-series data in the charging range at the early stage during the charging of the battery pack 20 according to the charging profile 40 including the plurality of charging ranges, and the predicted cell voltage time-series data increases faster than the second cell voltage time-series data in the charging range at the later stage of charging, the control unit 14 may increase the latent defect count of the corresponding cell by 1.

Additionally, when the latent defect count is equal to or larger than the reference number of times, the control unit 14 may finally determine the latent defect of the corresponding cell as lithium plating at the negative electrode.

Referring back to FIG. 1, the apparatus 10 according to the present disclosure may further include a recording storage medium 15 to store data, predefined parameters, programs or a combination thereof, and a display 16.

When the latent defective cell is detected according to the above-described embodiment, the control unit 14 may record identification information of the latent defective cell and/or information associated with the latent defect type in the recording storage medium 15 together with the time stamp.

The identification information of the latent defective cell includes the model code of the battery pack 20, the module code to which the latent defective cell belongs, the production lot number of the latent defective cell or a combination thereof. The information associated with the latent defect type may include diagnosis code indicating lithium plating at the negative electrode.

Additionally, when the latent defective cell is detected according to the above-described embodiment, the control unit 14 may be configured to output a message notifying that the latent defective cell is detected in the battery pack 20 through the display 16.

When the battery pack 20 is mounted in an electric vehicle, the display 16 may be a dashboard or an integrated automotive control display of the electric vehicle. In another example, when the battery pack 20 is mounted in an energy storage system, the display 16 may be a display included in an integrated control computer of the energy storage system. However, the present disclosure is not limited to the type of the display.

Meanwhile, the apparatus 10 according to the present disclosure may further include a communication interface 17. In this case, the control unit 14 may transmit the identification information associated with the latent defective cell and/or the information associated with the latent defect type to an external device through the communication interface 17.

The communication interface 17 supports wired or wireless communication. The communication interface 17 may support data transmission/reception by Controller Area Network (CAN), Daisy Chain, RS-232 or the like. Additionally, the communication interface 17 may support data transmission/reception via near-field ratio communication, for example, Wi-Fi, Bluetooth, Zigbee or the like. Additionally, the communication interface 17 may support wide area data transmission/reception via wired/wireless Internet, base station communication or satellite communication.

The external device may be the charging device 30. In another example, the external device may be a cloud server that collects status information of the battery pack 20. In still another example, the external device may be a diagnosis device that investigates the performance of the battery pack 20.

In the present disclosure, the control unit 14 may selectively include a processor, an application-specific integrated circuit (ASIC), a chipset, a logic circuit, a register, a communication modem, a data processing device or the like, well known in the corresponding technical field, to execute various control logics.

The recording storage medium 15 is not limited to a particular type, and may include any recording medium capable of recording and erasing information. In an example, the recording storage medium 15 may be hard disk, RAM, ROM, EEPROM, register or flash memory. The recording storage medium 15 may store and/or update and/or erase and/or transmit programs including the control logics executed by the control unit 14 and/or data generated when the control logics are executed and predefined lookup tables, functions, parameters, chemical/physical/electrical constants or the like.

At least one of the control logics of the control unit 14 may be combined together, and the combined control logics may be written in computer-readable code and recorded in the recording storage medium 15. The code may be stored and executed in distributed computers connected via a network. Additionally, the functional programs, code and code segments for implementing the combined control logics can be easily inferred by programmers in the technical field pertaining to the present disclosure.

The apparatus 10 according to the present disclosure may be included in a battery management system or a battery diagnosis system. The battery management system is a system that controls the entire operation of the battery pack 20. The battery management system may be an integrated control system included in a load device in which the battery pack 20 is mounted, for example, an electric vehicle and an energy storage system. In addition to the battery management system or the battery diagnosis system, the apparatus 10 according to the present disclosure may be included as part of any other device or system, if necessary.

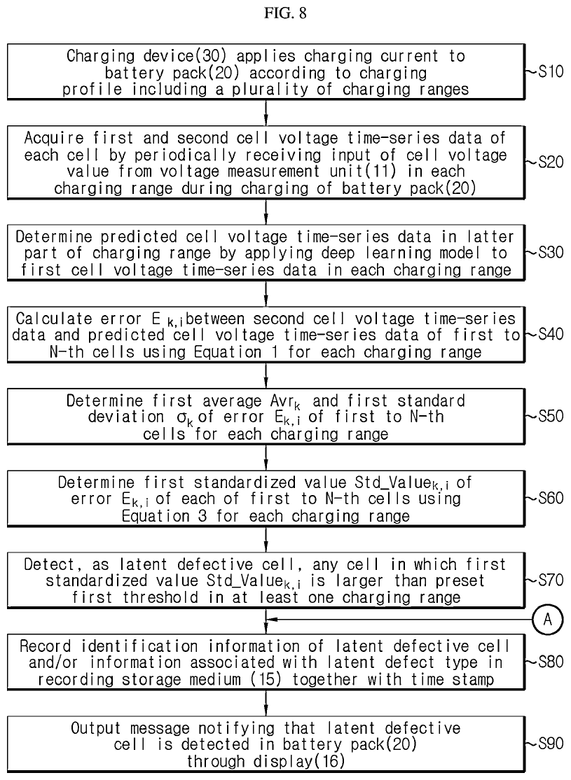

Hereinafter, a method for detecting a latent defective cell in a battery pack according to an embodiment of the present disclosure will be described with reference to FIGS. 8 to 10.

Referring to FIG. 8, first, in step S10, the charging device 30 applies the charging current to the battery pack 20 according to the charging profile 40 including the plurality of charging ranges. The charging device 30 may be the charging station of the electric vehicle or the PCS of the energy storage system.

The application of the charging current may start in response to a request from the control unit 14. That is, the control unit 14 may recognize the connection of a charging cable to the high potential line and low potential line of the battery pack 20, and request the charging device 30 to start to charge. Alternatively, when the charging device 30 is connected to the battery pack 20, the application of the charging current may automatically start.

Subsequently, in step S20, the control unit 14 acquires the first and second cell voltage time-series data by periodically receiving the input of the cell voltage value of the first to N-th cells in the battery pack 20 from the voltage measurement unit 11 in each charging range during the charging of the battery pack 20 according to the charging profile 40.

Subsequently, in step S30, apart from acquiring the first and second cell voltage time-series data through the voltage measurement unit 11 in each charging range, the control unit 14 determines the predicted cell voltage time-series data in the latter part of the corresponding charging range by applying the pre-trained deep learning model to the first cell voltage time-series data of the first to N-th cells in each charging range.

Subsequently, in step S40, the control unit 14 calculates the error E_{k,i} between the second cell voltage time-series data and the predicted cell voltage time-series data of the first to N-th cells in each charging range using Equation 1. In step S40, when the number of charging ranges is Num_{charge}, the total number of errors E_{k,i} is Num_{charge}*N.

Subsequently, in step S50, the control unit 14 determines the first average Avrₖ and the first standard deviation σₖ of the error E_{k,i} of the first to N-th cells for each charging range using Equation 2.

Subsequently, in step S60, the control unit 14 determines the first standardized value Std_Value_{k,i} of the error E_{k,i} of each of the first to N-th cells using Equation 3 for each charging range. When the number of charging ranges is Num_{charge}, the total number of first standardized values Std_Value_{k,i} is Num_{charge}*N.

Subsequently, in step S70, the control unit 14 may detect, as the latent defective cell, any cell in which the first standardized value Std_Value_{k,i} is larger than the preset first threshold in at least one charging range.

After the step S70, step S80 or S90 may be selectively performed.

In the step S80, when the latent defective cell is detected, the control unit 14 may record the identification information of the latent defective cell and/or the information associated with the latent defect type in the recording storage medium 15 together with the time stamp. The identification information of the latent defective cell includes the model code of the battery pack 20, the module code to which the latent defective cell belongs, the production lot number of the latent defective cell or a combination thereof. The information associated with the latent defect type may include the diagnosis code indicating lithium plating at the negative electrode.

Additionally, in the step S90, when the latent defective cell is detected, the control unit 14 may output the message notifying that the latent defective cell is detected in the battery pack 20 through the display 16. In response to the output of the message, the user may stop using the battery pack 20 or replace the battery pack 20, or request a repair shop or an after service center to investigate the battery pack 20 in detail.

Meanwhile, the step S50 may be omitted. In this case, the first average Avrₖ and the first standard deviation σₖ may be pre-determined in the training process of the deep learning model. That is, after the training of the deep learning model is completed, the error E_{k,i} of each charging range may be determined for each training cell during the charging of the first to m-th training cells according to the charging profile 40. Additionally, the average and the standard deviation of the error E_{k,i} may be calculated using Equation 2 for each charging range and each calculated value may be preset to the first average Avrₖ and the first standard deviation σₖ. The first average Avrₖ and the first standard deviation σₖ set in the training process of the deep learning model may be pre-stored in the recording storage medium 15, and when the step S60 is performed, the pre-stored information may be referred by the control unit 14.

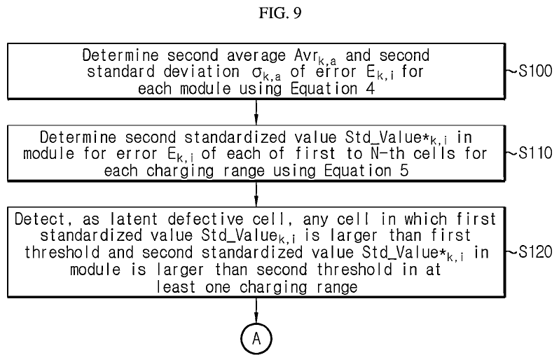

In a preferred embodiment, the steps after the step S60 may be modified as shown in FIG. 9.

That is, in step S100, the control unit 14 may determine the second average Avr_{k,a} and the second standard deviation σ_{k,a} of the error E_{k,i} in each charging range for each module using Equation 4.

Subsequently, in step S110, the control unit 14 determines the second standardized value Std_Value*_{k,i} in the module for the error E_{k,i} of each of the first to N-th cells for each charging range using Equation 5. When the number of charging ranges is Num_{charge}, the number of second standardized values Std_Value*_{k,i} in the module for each cell is Num_{charge}.

Subsequently, in step S120, the control unit 14 may detect, as the latent defective cell, any cell in which the first standardized value Std_Value_{k,i} is larger than the first threshold and the second standardized value Std_Value*_{k,i} in the module is larger than the second threshold in at least one charging range.

Preferably, the second threshold may be smaller than the first threshold. In an example, the first threshold may be 3.0 or more, preferably 4.0 or more, and more preferably 4.5 or more. Additionally, the second threshold may be preferably set to 3.0 or less, and more preferably 2.5 or less.

After the step S120, in the same way as the above-described embodiment, the step S80 or S90 may be performed substantially equally.

That is, when the latent defective cell in the battery pack 20 is detected, the control unit 14 may record the identification information of the latent defective cell and/or the information associated with the latent defect type in the recording storage medium 15 together with the time stamp. The identification information of the latent defective cell includes the model code of the battery pack 20, the module code to which the latent defective cell belongs, the production lot number of the latent defective cell or a combination thereof. The information associated with the latent defect type may include the diagnosis code indicating lithium plating at the negative electrode.

Additionally, when the latent defective cell in the battery pack 20 is detected, the control unit 14 may output the message notifying that the latent defective cell is detected in the battery pack 20 through the display 16.

The method for detecting a latent defective cell in a battery pack according to the present disclosure may further include identifying the latent defect type of the battery cell.

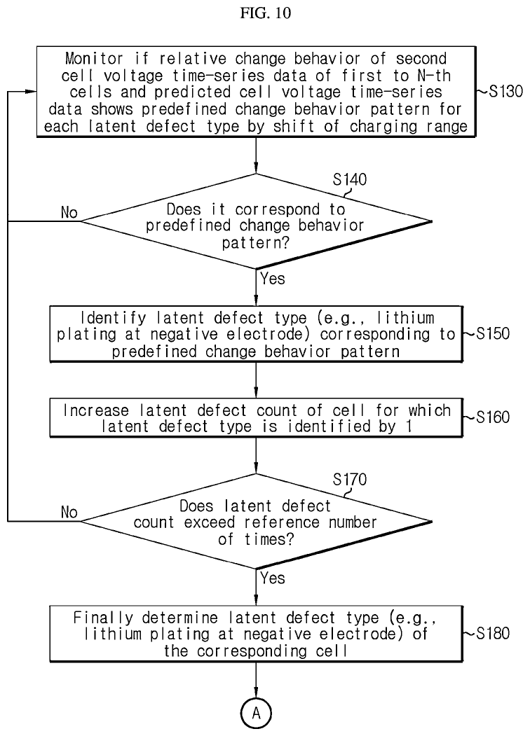

As shown in FIG. 10, in step S130, the control unit 14 may monitor if the relative change behavior of the second cell voltage time-series data of the first to N-th cells measured in the latter part of each charging range and the predicted cell voltage time-series data predicted in the latter part of each charging range as the charging range shifts shows the predefined change behavior pattern for each latent defect type.

In an embodiment, the control unit 14 may monitor if there is any of the first to N-th cells showing the behavior pattern in which the second cell voltage time-series data increases faster than the predicted cell voltage time-series data in the charging range at the early stage of charging, and the predicted cell voltage time-series data increases faster than the second cell voltage time-series data in the charging range at the later stage of charging.

Subsequently, in step S140, the control unit 14 determines if the relative change behavior of the second cell voltage time-series data and the predicted cell voltage time-series data corresponds to the predefined change behavior pattern for the latent defect type.

When the result of the step S140 is YES, step S150 is performed. On the contrary, when the result of the step S140 is NO, the process reverts to the step S130.

When the result of the step S140 is YES, the control unit 140 identifies the latent defect type corresponding to the predefined change behavior pattern in the step S150. In an embodiment, when the control unit 14 detects any of the first to N-th cells showing the behavior pattern in which the second cell voltage time-series data increases faster than the predicted cell voltage time-series data in the charging range at the early stage of charging, and the predicted cell voltage time-series data increases faster than the second cell voltage time-series data in the charging range at the later stage of charging, the control unit 14 may identify the latent defect of the corresponding cell as lithium plating at the negative electrode.

Subsequently, in step S160, the control unit 14 increases by 1 the latent defect count of the corresponding cell for which the latent defect type (for example, lithium plating at the negative electrode) is identified.

Subsequently, in step S170, the control unit 14 determines if the latent defect count exceeds the reference number of times.

When the determination of the step S170 is YES, step S180 is performed. On the contrary, when the determination of S170 is NO, the process reverts to the step S130.

When the determination of the step S170 is YES, the control unit 14 finally determines the latent defect type (for example, lithium plating at the negative electrode) for the cell in which the latent defect count is larger than the reference number of times in the step S180.

After the step S180 is performed, in the same way as the above-described embodiment, the step S80 or S90 may be performed.

That is, when the latent defect of the specific cell in the battery pack 20 is identified and the latent defect type is finally determined, the control unit 14 may record the identification information of the latent defective cell and the information associated with the latent defect type in the recording storage medium 15 together with the time stamp. The identification information of the latent defective cell includes the model code of the battery pack 20, the module code to which the latent defective cell belongs, the production lot number of the latent defective cell or a combination thereof. The information associated with the latent defect type may include the diagnosis code indicating lithium plating at the negative electrode.

Additionally, when the latent defective cell is identified in the battery pack 20 and the latent defect type is finally determined, the control unit 14 may output the message notifying that the latent defective cell is detected in the battery pack 20 through the display 16 together with the information associated with the latent defect type.

Meanwhile, the control unit 14 may transmit the identification information associated with the latent defective cell and/or information associated with the latent defect type to the external device through the communication interface 17. The communication interface 17 may support wired communication or wireless communication.

The external device may be the charging device 30. In another example, the external device may be a cloud server that collects status information of the battery pack 20. In still another example, the external device may be a diagnosis device that investigates the performance of the battery pack 20.

In the present disclosure, in addition to lithium plating at the negative electrode, the latent defect type may include any other latent defect type, for example, cell swelling, a micro internal short circuit or the like. For each latent defect type, it is obvious to those skilled in the art that the relative change behavior pattern of the second cell voltage time-series data and the predicted cell voltage time-series data as the charging range shifts can be easily determined through the test.

According to the present disclosure, it is possible to easily detect a latent defective cell by dividing the charging profile of the battery pack 20 into the plurality of charging ranges, and statistically comparing and analyzing the behaviors of the actually measured voltage and the predicted voltage for each charging range. Accordingly, it is possible to prevent human accidents by detecting latent defects directly related to fire or explosion accidents, especially, serious latent defects such as lithium plating at the negative electrode in the early stage and providing warnings to users. Additionally, in addition to the lithium plating at the negative electrode, the present disclosure may detect voltage change behaviors caused by swelling, micro short circuits or the like, thereby effectively dealing with other latent defects.

While the present disclosure has been hereinabove described with regard to a limited number of embodiments and drawings, the present disclosure is not limited thereto and it is obvious to those skilled in the art that various modifications and changes may be made thereto within the technical aspects of the present disclosure and the appended claims and equivalents thereof.

1. An apparatus for detecting one or more latent defective cells in a battery pack, comprising:
a voltage sensor, a current sensor and a temperature sensor to measure a voltage, a current and a temperature of first to N-th cells included in the battery pack during charging of the battery pack, respectively, and
a controller connected to the voltage sensor, the current sensor and the temperature sensor,
wherein the controller is configured to, during the charging of the battery pack according to a charging profile having a plurality of charging ranges, for each of the first to N-th cells:
in each charging range of the plurality of charging ranges:
acquire first cell voltage time-series data through the voltage sensor in a former part of the charging range;
determine predicted cell voltage time-series data in a latter part of the charging range by applying a deep learning model to the first cell voltage time-series data;
acquire second cell voltage time-series data through the voltage sensor in the latter part of the charging range; and
determine an error between the second cell voltage time-series data and the predicted cell voltage time-series data; and
determine that any cell in which the determined error is larger than corresponding errors of other cells in at least one of the plurality of charging ranges is one of the latent defective cells.

2. The apparatus for detecting a latent defective cell in a battery pack according to claim 1, wherein the error is a maximum difference between the second cell voltage time-series data and the predicted cell voltage time-series data, and wherein the controller is configured to:
for each of the plurality of charging ranges:
determine a first average of the errors of the first to N-th cells and a first standard deviation of the errors of the first to N-th cells;
for each error of the first to N-th cells, compute a first standardized value of the error that is equal to a ratio of (i) a difference between the error−and the first average to (ii) the first standard deviation; and
determine that any cell in which the first standardized value is larger than the first threshold in at least one of the plurality of charging ranges is one of the latent defective cells.

3. The apparatus for detecting a latent defective cell in a battery pack according to claim 1, wherein the deep learning model is pre-trained, using the first cell voltage time-series data and the second cell voltage time-series data of first to m-th training cells respectively measured in the former part and the latter part of each of the plurality of charging ranges, to receive an input of the first cell voltage time-series data and output a predicted cell voltage time-series data having a minimum error compared to the second cell voltage time-series data.

4. The apparatus for detecting a latent defective cell in a battery pack according to claim 3, wherein the error is a maximum difference between the second cell voltage time-series data and the predicted cell voltage time-series data, and wherein the controller is configured to:
for each of the plurality of charging ranges:
for each error of the first to N-th cells, compute a first standardized value of the error that is equal to a ratio of (i) a difference between the error and−a first average to (ii) a first standard deviation and
determine any cell in which the first standardized value is larger than a first threshold in at least one of the plurality of charging ranges is one of the latent defective cells, and
wherein the first average and the first standard deviation are pre-determined by the deep learning model during a training process of the deep learning model.

5. The apparatus for detecting a latent defective cell in a battery pack according to claim 2, wherein the battery pack includes first to p-th modules connected in series or in parallel, and
wherein the controller is configured to:
for each of the first to p-th modules:
determine a second average and a second standard deviation of the error of those cells of the first to N-th cells that are included in the module; and
for each error of those cells of the first to N-th cells that are included in the module, compute a second standardized value of the error that equals a ratio of (i) a difference between the error−and the second average to (ii) the second standard deviation; and
determine that any cell in which the first standardized value is larger than the first threshold and the second standardized value is larger than a second threshold in at least one of the plurality of charging ranges is one of the latent defective cells.

6. The apparatus for detecting a latent defective cell in a battery pack according to claim 1, wherein the controller is configured to, for each of the first to N-th cells:
monitor if a relative change behavior of the second cell voltage time-series data and the predicted cell voltage time-series data in each of the plurality of the charging ranges shifts matches a predefined change behavior pattern for a latent defect type; and
determine whether the latent defect type of any cell in which the predefined change behavior pattern is found occurs within a reference number of times or more.

7. The apparatus for detecting a latent defective cell in a battery pack according to claim 6, wherein the predefined change behavior pattern occurs when the second cell voltage time-series data increases faster than the predicted cell voltage time-series data in any of the plurality of charging ranges at a first stage of charging and the predicted cell voltage time-series data increases faster than the second cell voltage time-series data in any of the plurality of charging ranges at a second stage of charging after the first stage, and
wherein the latent defect type includes a lithium plating at a negative electrode.

8. The apparatus for detecting a latent defective cell in a battery pack according to claim 1, further comprising:
a storage medium configured to store data, a predefined parameter, a program or a combination thereof; and
a display,
wherein the controller is configured to record identification information associated with the determined latent defective cell in the storage medium, or output a message notifying that the latent defective cell is detected in the battery pack through the display, or transmit the identification information of the latent defective cell to an external device.

9. A battery management system comprising the apparatus for detecting a latent defective cell in a battery pack according to claim 1.

10. A method for detecting a latent defective cell in a battery pack, comprising:
during charging of the battery pack according to a charging profile having a plurality of charging ranges, for each of first to N-th cells in each charging range,
in each charging range of the plurality of charging ranges:
acquiring first cell voltage time-series data in a former part of the charging range;
determining predicted cell voltage time-series data in a latter part of each of the plurality of charging ranges by applying a deep learning model to the first cell voltage time-series data;
acquiring second cell voltage time-series data in the latter part of each of the plurality of charging ranges;
determining an error between the second cell voltage time-series data and the predicted cell voltage time-series data; and
determining that any cell in which the determined error is larger than corresponding errors of other cells in at least one of the plurality of charging ranges is one of the latent defective cell.

11. The method for detecting a latent defective cell in a battery pack according to claim 10, wherein the error is a maximum difference between the second cell voltage time-series data and the predicted cell voltage time-series data, wherein the controller is configured to:
for each of the plurality of charging ranges:
determining a first average of the errors of the first to N-th cells and a first standard deviation of the errors of the first to N-th cells;
for each error of the first to N-th cells, compute a first standardized value of the error that is equal to a ratio of (i) a difference between
computing the error and−the first average to (ii) the first standard deviation; and
determining any cell in which the first standardized value is larger than the first threshold in at least one of the plurality of charging ranges is one of the latent defective cells.

12. The method for detecting a latent defective cell in a battery pack according to claim 10, wherein the deep learning model is pre-trained, using the first cell voltage time-series data and the second cell voltage time-series data of first to m-th training cells measured in the former part and the latter part of each of the plurality of charging ranges, to receive an input of the first cell voltage time-series data and output a predicted cell voltage time-series data having a minimum error compared to the second cell voltage time-series data.

13. The method for detecting a latent defective cell in a battery pack according to claim 12, wherein the error is a maximum difference between the second cell voltage time-series data and the predicted cell voltage time-series data, and wherein the controller is configured to:
for each of the plurality of charging ranges:
for each error of the first to N-th cells,
computing a first standardized value of the error that is equal to a ratio of (i) a difference between the error and−a first average to (ii) a first standard deviation; and
determining any cell in which the first standardized value is larger than a first threshold in at least one of the plurality of charging ranges is one of the latent defective cells, and
wherein the first average and the first standard deviation are pre-determined values by the deep learning model during a training process of the deep learning model.

14. The method for detecting a latent defective cell in a battery pack according to claim 11, wherein the battery pack includes first to p-th modules connected in series or in parallel, and
wherein the method further comprises, for each of the first to p-th modules, determining a second average and a second standard deviation of the error of those cells of the first to N-th cells that are included in the module;
for each error of those cells of the first to N-th cells that are included in the module,
computing a second standardized value of the error that equals a ratio of (i) a difference between the error and−the second average; to (ii) the second standard deviation; and
determining that any cell in which the first standardized value is larger than the first threshold and the second standardized value is larger than a second threshold in at least one of the plurality of charging ranges is one of the latent defective cells.

15. The method for detecting a latent defective cell in a battery pack according to claim 10, further comprising:
for each of the first to N-th cells, monitoring a relative change behavior of the second cell voltage time-series data and the predicted cell voltage time-series data to determine whether a charging range shifts according to a predefined change behavior pattern for a latent defect type; and
determining whether the latent defect type of any cell in which the predefined change behavior pattern is found occurs within a reference number of times or more.

16. The method for detecting a latent defective cell in a battery pack according to claim 15, wherein the predefined change behavior pattern occurs when the second cell voltage time-series data increases faster than the predicted cell voltage time-series data in any of the plurality of charging ranges at a first stage of charging and the predicted cell voltage time-series data increases faster than the second cell voltage time-series data in any of the plurality of charging ranges at a second stage of charging after the first stage, and
wherein the latent defect type includes a lithium plating at a negative electrode.

17. The method for detecting a latent defective cell in a battery pack according to claim 10, further comprising:
recording identification information associated with the determined latent defective cell in a storage medium;
outputting a message notifying that the latent defective cell is detected in the battery pack through a display; or
transmitting the identification information of the latent defective cell to an external device.
